(19) United States
(12) Patent Application Publication
(10) Pub. No.: US 2008/0016429 A1
(43) Pub. Date: Jan. 17, 2008

(54) Data storage device and error correction method

(75) Inventors: Kenichi Saneshige, Kanagawa (JP); Yasuhiro Takase, Kanagawa (JP); Haruo Andoh, Kanagawa (JP); Tomoharu Maeno, Kanagawa (JP)

Correspondence Address: TOWNSEND AND TOWNSEND AND CREW LLP, TWO EMBARCADERO CENTER, 8TH FLOOR, SAN FRANCISCO, CA, 94111, US

(73) Assignee: Hitachi Global Storage Technologies Netherlands B.V., Amsterdam (NL)

(21) Appl. No.: 11/787,109

(22) Filed: Apr. 12, 2007

(30) Foreign Application Priority Data
Apr. 13, 2006 (JP) 2006-111185

(51) Int. Cl. G11C 29/00

(52) U.S. Cl. 714/763

(57) ABSTRACT

Embodiments in accordance with the present invention increase the reliability of a data storage device, and to reduce the circuit size. According to one embodiment of the present invention, a hard disk drive (HDD) executes not only error correction processing of data to be written to a magnetic disk, but also error correction processing of data stored in the DRAM. In the HDD according to this embodiment, one SRAM is shared by both kinds of error correction processing. As a result of executing the error correction processing of the data stored in the DRAM, the reliability of the HDD is improved. In addition, by using the same SRAM for the two kinds of error correction processing that differ from each other, it is possible to suppress the increase in circuit size.

### CROSS-REFERENCE TO RELATED APPLICATION

The instant nonprovisional patent application claims priority to Japanese Application No. 2006-111185, filed Apr. 13, 2006 and incorporated by reference in its entirety herein for all purposes.

### BACKGROUND OF THE INVENTION

Devices using various types of media such as optical discs, magnetic optical discs, and flexible magnetic disk are known in the art as data storage devices. Among them, hard disk drives (hereinafter referred to as HDDs) have become popular as storage devices for computers to such an extent that they are one of the storage devices indispensable for today's computer systems. Further, not limited to the computers as described above, HDDs are becoming more and more widely used in various applications. For example, HDDs are used for video recording/reproducing devices, car navigation systems, cellular phones, and as removable memories for use in digital cameras.

The HDD includes not only a magnetic disk used as a non-volatile medium for storing data, but also a buffer memory for temporarily storing user data. The HDD has a cache function that uses the buffer memory. Typically, the HDD has both a read cache function and a write cache function. The cache function makes up the difference between the medium access rate in the HDD and the data transmission rate between a host and the HDD, and thus reduces the delay in the data transmission between the host and the HDD.

The buffer memory is required to have more capacity to increase the cache capacity. Accordingly, a DRAM is typically used as the buffer memory. Recently, the capacity of buffer memories increases with the increase in performance of HDDs. In addition, the access speed thereof also increases. Following this tendency, there is also an increasing probability that a defect will occur in a DRAM.

For this reason, in order to increase the reliability as a HDD, the HDD performs error correction processing of data written to a magnetic disk, and also performs error correction processing of data stored in a buffer memory. To be more specific, the HDD adds an ECC (Error Correcting Code) to user data transmitted from a host, and then stores the user data in the buffer memory. When the HDD reads out data from the buffer memory to transmit the data to the magnetic disk, the HDD executes the error correction processing by use of the ECC. In addition, also when the HDD transmits data from the buffer memory to the host, the HDD executes the error correction processing by use of the ECC.

Incidentally, although the purpose and the configuration are different from those of the present invention, Japanese Laid-Open Patent No. 2002-023966 (“patent document 1”) discloses that a disk system including a host and a plurality of HDDs uses the same ECC to perform error correction that is consistent throughout the whole system.

In order to perform the error correction processing of data to be stored in the buffer memory, it is necessary to configure a HDD to perform not only error correction of data in a magnetic disk, but also error correction of data to be stored in the buffer memory. However, if this error correction processing is performed only by a dedicated hardware circuitry, the circuit size becomes larger, which leads to an increase in cost.

Here, it is thought that part of the error correction processing of data to be stored in the buffer memory is executed by software. If a MPU executes the part of the error correction processing according to codes, it is easily implement an error correction function in the HDD. As a result, it is possible to reduce the size of a hardware circuit, and thereby prevent a circuit design period from being extended over a long period of time, and avoid the large increase in cost.

As a method for correcting an error of data in a buffer memory by a MPU, it is thought that when an error is detected in data transmitted from the buffer memory to a magnetic disk, the MPU corrects the data in the buffer memory, and then transmits the data from the buffer memory to the magnetic disk again. However, if this technique is adopted, it is difficult to identify a cause of the error. To be more specific, it is difficult to identify a cause of the error from among the following cases: an error exists in data that is cached in the buffer memory; a defect exists in a cell of the buffer memory; and an error has occurred while data is being transmitted.

If data is corrupted, it is possible to cope with the corrupted data by performing the error correction in the buffer memory. However, if a cell of the buffer memory is stacked, or if a transmission path is defective, an error will repeatedly occur even if the error correction is performed in the buffer memory. Therefore, if error correction is performed by the MPU, it is necessary, for example, to make a retry to identify the cause, and to make a copy to another position to perform the error correction. As a result, the code sizes increase, and accordingly, the processing time becomes longer, which causes a decrease in performance.

### BRIEF SUMMARY OF THE INVENTION

An object of the present invention is to increase the reliability of a data storage device, and to reduce the circuit size. According to the particular embodiment disclosed in FIG. 1 of the present invention, HDD 1 executes not only error correction processing of data to be written to a magnetic disk 11, but also error correction processing of data stored in the DRAM 24. In the HDD 1 according to this embodiment, one SRAM 318 is shared by both kinds of error correction processing. As a result of executing the error correction processing of the data stored in the DRAM 24, the reliability of the HDD 1 is improved. In addition, by using the same SRAM 318 for the two kinds of error correction processing that differ from each other, it is possible to suppress the increase in circuit size.

### BRIEF DESCRIPTION OF THE DRAWINGS

FIG. 1 is a block diagram schematically illustrating an overall configuration of a hard disk drive according to an embodiment of the present invention.

FIG. 2 is a block diagram illustrating the flow of read processing and write processing according to an embodiment of the present invention.

FIG. 3 is a flowchart illustrating processing performed when a system error is not detected in the write processing according to an embodiment of the present invention.

FIG. 4 is a flowchart illustrating error correction processing performed in the read processing according to an embodiment of the present invention.

FIG. 5 is a block diagram schematically illustrating a logical configuration relating to system error correction according to an embodiment of the present invention.

FIG. 6 is a flowchart illustrating processing performed when a system error is detected in the write processing according to an embodiment of the present invention.

FIG. 7 is a block diagram schematically illustrating a logical configuration relating to medium error correction according to an embodiment of the present invention.

### DETAILED DESCRIPTION OF THE INVENTION

Embodiments in accordance with the present invention relate to a data storage device and an error correction method thereof, and more particularly to error correction of data transmitted from a buffer memory to a medium.

According to one aspect of the present invention, a data storage device is provided, the data storage device comprising:

a buffer memory for storing write data received from the outside;

a first error correction part for executing error correction processing of the write data that is transmitted from the buffer memory to a medium;

a second error correction part for executing error correction processing of read data read out from the medium; and

an error correction memory for temporarily storing the write data from the buffer memory, and for temporarily storing the read data read out from the medium, the write data being subjected to the error correction processing of the first error correction part, the read data being subjected to the error correction processing of the second error correction part.

Because the error correction processing of the first error correction part and that of the second error correction part share the error correction memory, it is possible to reduce the circuit size.

The first error correction part may be a processor which operates according to codes, and that the second error correction part be a hardware circuit for executing the error correction processing on the fly. While avoiding the delay in data transmission to a host, the processor is used. This makes it possible to reduce the circuit size.

The data storage device according to an embodiment of the present invention further comprises an error check circuit for checking an error of the write data that is transmitted from the buffer memory to the medium. In parallel with the processing of the error check circuit, the write data from the buffer memory is stored in the error correction memory. In addition, in parallel with the processing of the error check circuit, the write data is transmitted to the medium. If the error check circuit detects an error, the first error correction part executes the error correction processing of the write data in which the error has been detected. Thus, because the error checking can be performed on the fly, it is possible to prevent the data transmission from being delayed in the case where no error exists.

Preferably, the data storage device further comprises: a path through which data is transmitted from the buffer memory to the error check circuit; and a path through which data is transmitted from the error correction memory to the error check circuit, wherein if the first error correction part executes the error correction, the path through which data is transmitted from the error correction memory to the error check circuit is selected. This makes it possible to check again the data after the correction.

Preferably, the error correction memory comprises a plurality of pages of buffer; the read data from the medium is successively inputted into each of the plurality of pages, and is output from the error correction memory in the order of the input; the write data from the buffer memory is stored in part of the plurality of pages; the first error correction part obtains data for identifying a page in which the write data is stored, and then executes the error correction processing of the stored write data; and the error correction memory selects the page in which the write data whose error has been corrected is stored, and then outputs the data from the page. If the second error correction part uses the plurality of pages to perform the error correction processing, it is possible to appropriately use part of the buffer by the first error correction part.

The data storage device further comprises an ECC addition circuit for adding an ECC to the write data received from the outside, wherein: the buffer memory temporarily stores the write data to which the ECC is added; and the error check circuit uses the ECC to execute error detection processing of the write data transmitted from the buffer memory. This makes it possible to perform the error correction of the buffer memory and that of the whole transmission path thereof.

It is desirable that the first error correction part obtain an error position and an error pattern from the error check circuit to execute the error correction of the write data. This makes it possible to efficiently perform the error correction processing.

According to another aspect of the present invention, a method is provided for performing error correction of data in a data storage device, the method comprising the steps of:

storing, in a memory, write data that is transmitted from a buffer memory to a medium;

executing error correction processing of the write data stored in the memory;

transmitting, to the medium, the write data whose error has been corrected;

storing, in the memory, read data read out from the medium; and

executing error correction processing of the read data stored in the memory.

Because the memory is shared by the two kinds of error correction processing, it is possible to reduce the circuit size.

Preferably, the write data to which an ECC is added is stored in the buffer memory; the write data having the ECC, which is transmitted from the buffer memory to the medium, is stored in the memory; and if an error is detected in the write data transmitted from the buffer memory, error correction processing of the write data stored in the memory is executed by use of the ECC. This makes it possible to perform the error correction of the buffer memory and that of the whole transmission path thereof.

Preferably, the error check processing of the write data to be transmitted to the medium is executed; in parallel with the error check processing, the write data to be transmitted to the medium is stored in the memory; and if an error is detected in the write data during the error check processing, error correction processing of the write data stored in the memory is executed. This makes it possible to prevent the transmission from being delayed by error checking, and also to increase the efficiency in error correction processing.

Preferably, the read data from the medium is successively inputted into each of a plurality of pages of the memory and output from the memory in the order of the input; the write data from the buffer memory is stored in one of the plurality of pages; error correction processing of the stored write data is executed; and after selecting the page in which the write data whose error has been corrected is stored, the data is output from the page.

According to the present invention, it is possible to improve the reliability of a data storage device, and to reduce the circuit size thereof.

Embodiments of the present invention will be described as below. For clarification of the explanation, omission and simplification are made, where appropriate, in the following description and drawings. Also note that identical reference numerals are used to designate identical elements that are common to the figures, and that redundant description is omitted as appropriate for clarification of the explanation. As an example of data storage devices, there are hard disk drives. Taking a hard disk drive (HDD) as an example, an embodiment of the present invention will described as below.

One of the characteristics of this embodiment is a technique for user-data error correction processing. A HDD according to this embodiment executes not only error correction processing of data to be written to a magnetic disk but also error correction processing of data stored in a buffer memory. In the HDD according to this embodiment, one memory is shared by both types of error correction processing. As a result of executing the error correction processing of data stored in the buffer memory, the reliability of the HDD is improved. In addition, by using the same memory for the two kinds of error correction processing that differ from each other, it is possible to suppress the increase in circuit size.

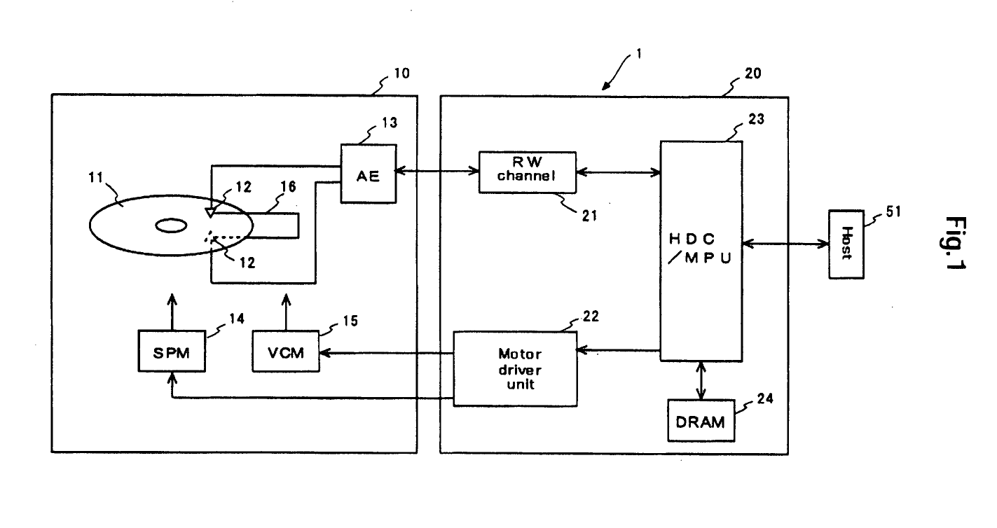

For easier understanding of the characteristics of this embodiment, first of all, an overall configuration of the HDD will be described. FIG. 1 is a block diagram schematically illustrating an overall configuration of a HDD 1 according to this embodiment. As shown in FIG. 1, the HDD 1 comprises an enclosure 10, which houses: a magnetic disk 11 that is an example of a medium (recording medium); head elements 12; arm electronics (AE) 13; a spindle motor (SPM) 14; a voice coil motor (VCM) 15; and an actuator 16.

The HDD 1 further includes a circuit board 20 that is secured outside the enclosure 10. On the circuit board 20, there are provided ICs including: a read/write channel (R/W channel) 21; a motor driver unit 22; an integrated circuit 23 including a hard disk controller (HDC) and a MPU (hereinafter referred to as “HDC/MPU”); and a DRAM 24 that is an example of a buffer memory. Incidentally, the above-described circuits may be integrated into one IC; or each circuit may be implemented by dividing the circuit into a plurality of ICs.

The SPM 14 rotates the magnetic disk 11 secured at the SPM 14 at specified angular speed. The motor driver unit 22 drives the SPM 14 according to control data sent from the HDC/MPU 23. The magnetic disk 11 according to this embodiment has recording surfaces on both sides. Data is written to each of the recording surfaces. Each recording surface is provided with its corresponding head element 12.

Each head element 12 is secured to a slider (not illustrated in the figure). The slider is secured to the actuator 16. The actuator 16 is connected to the VCM 15. The actuator 16 pivotally moves about a pivot shaft, which causes the head element 12 (and the slider) to move in the radial direction on the magnetic disk 11. The motor driver unit 22 drives the VCM 15 according to control data sent from the HDC/MPU 23. The head element 12 includes: a write element for converting an electric signal into a magnetic field according to write data; and a read element for converting a magnetic field received from the magnetic disk 11 into an electric signal. It is to be noted that the required number of the magnetic disks 11 is one or more, and that a recording surface can be formed on one side, or both sides, of the magnetic disk 11. In addition, the present invention can also be applied to a data storage device that includes only a read element.

The AE 13 selects from among the plurality of head elements 12 one head element 12 that is used to access data, and amplifies (preamplifies), at constant gain, a read signal read by the selected head element 12, and then transmits the amplified signal to the RW channel 21. In addition, the AE 13 receives a write signal from the RW channel 21, and then transmits the write signal to the selected head element 12.

In the write processing, the RW channel 21 performs code modulation of write data supplied from the HDC/MPU 23, and then converts the code-modulated write data into a write signal to supply the write signal to the AE 13. In the read processing, the RW channel 21 amplifies a read signal supplied from the AE 13 so that the amplitude thereof is kept constant, and then extracts data from the obtained read signal to perform decode processing. Data which is read out includes user data and servo data. The decoded read data is supplied to the HDC/MPU 23.

In the HDC/MPU 23, the MPU operates according to microcodes loaded into the DRAM 24. When the HDD 1 is started up, not only the microcodes that operate on the MPU, but also the data required for control and data processing are loaded into the DRAM 24 from the magnetic disk 11 or a ROM (not illustrated in the figure). The HDC is configured as a hardware logic circuit. The HDC executes various kinds of processing in cooperation with the MPU in a unified manner. For example, the HDC/MPU 23 executes processing required for data processing such as management of the command execution order, positioning control of the head elements 12, interface control, and defect control, and also executes the entire control of the HDD 1. Further, the HDC/MPU 23 executes error correction processing of user data, which has been obtained from the host, or which has been read out from the magnetic disk 111. The HDC/MPU 23 according to this embodiment is characterized by error correction processing of user data. This point is described in detail later.

After the HDC/MPU 23 receives read data from the magnetic disk 11 through the RW channel 21, the HDC/MPU 23 temporarily stores the read data in a read buffer included in the DRAM 24, and then transmits the read data to the host 51. In addition, the HDC/MPU 23 temporarily stores write data received from the host 51 in a write buffer included in the DRAM 24, and then transmits the write data to the magnetic disk 11 in the specified timing.

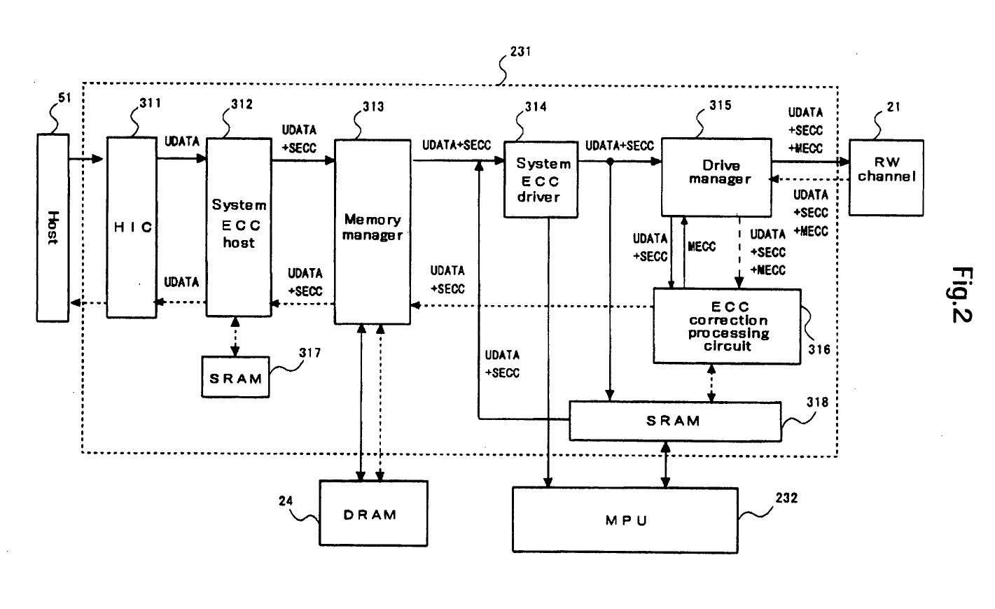

As described above, the HDC/MPU 23 according to this embodiment executes the error correction processing of user data read out from the magnetic disk 11, and also executes the error correction processing of data read out from the DRAM 24. Next, the process flow of the error correction processing at the time of writing/reading user data will be described with reference to FIG. 2. Incidentally, in this specification, the error correction processing of data received from the magnetic disk 11 is designated as medium error correction processing, whereas the error correction processing of data received from the DRAM 24 is designated as system error correction processing.

FIG. 2 is a block diagram schematically illustrating not only part of the HDC/MPU 23 in detail, but also the DRAM 24. The HDC/MPU includes a HDC 231 formed of a hardware circuit, and a MPU 232 that operates according to codes. The HDC 231 includes a host interface controller (HIC) 311, a system ECC (Error Correcting Code) host 312, a memory manager 313, a system ECC driver 314, a drive manager 315, an ECC correction processing part 316 (an example of an error correction processing part), a SRAM 317, and a SRAM 318.

The HDC 231 according to this embodiment uses the SRAM 318 during both the medium error correction processing and the system error correction processing. Thus, as a result of sharing one SRAM 318 by the two kinds of error correction processing, it is possible to reduce the circuit size of the HDC 231. During read processing, an error of data read out from the magnetic disk 11 is corrected by the medium error correction processing. On the other hand, during write processing, an error of data to be written to the magnetic disk 11 is corrected by the system error correction processing. Therefore, it is possible to share the same memory 318 without the interference of the processing with each other. A data transmission flow during write processing and read processing will be described with reference to FIG. 2.

In FIG. 2, each solid line arrow indicates the flow of data (write data) that is transmitted from the host 51 and is then written to the magnetic disk 11. On the other hand, each dotted line arrow indicates the flow of data (read data) that is read out from the magnetic disk 11 and is then transmitted to the host 51. Incidentally, during both read processing and write processing, data is transmitted and processed on a data sector basis. Here, a data sector is a unit of writing user data to the magnetic disk 11. A system ECC and a medium ECC are generated on a data sector basis.

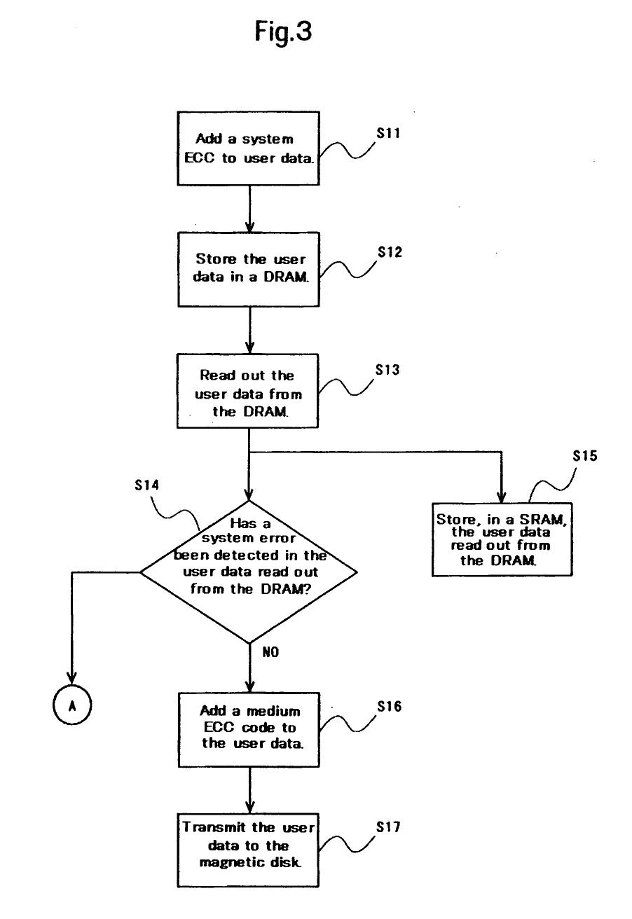

First of all, write processing will be described with reference to the block diagram in FIG. 2 and a flowchart in FIG. 3. HIC 311 is an interface circuit for interfacing between the host 51 and the HDD 1. At the time of write processing, through a data bus, the HIC 311 supplies the system ECC host 312 with user data (UDATA) transmitted from the host 51. The system ECC host 12 generates a system ECC (SECC), and then adds the system ECC to the user data (S11).

The system ECC is a code for correcting an error in the HDC 231. The system ECC is an ECC used to correct an error that may occur in each of a phase of transmission and writing to the DRAM 24 and a phase of reading and transmission. This embodiment will be described on the assumption that an ECC code and a CRC (Cyclic Redundancy Check) code are added as system ECCs. However, only ECC may also be used in this embodiment. As the ECC and CRC codes, for example, Reed-Solomon codes can be used. Processing of the system ECC host 312 is executed on the fly so that data transmission from the host 51 is not interrupted. Accordingly, the system ECCs are generated without substantially hindering the flow of data transmission. Here, the on-the-fly processing means that processing is executed without interrupting data transmission.

The system ECC host 312 transmits user data including system ECCs to the memory manager 313 through the data bus. The memory manager 13 temporarily stores the received user data with the system ECCs in a read buffer included in the DRAM 24 (S12). After that, upon the receipt of a request from the drive manager 315, the memory manager 13 reads out the data from the DRAM 24, and then transmits the data to the system ECC driver 314 through the data bus (S13).

When the system ECC driver 314, which is an example of an error check circuit, receives the user data with the system ECCs, the system ECC driver 314 executes error check processing by use of the system ECCs (S14). The system ECC driver 314 checks an error of the user data. However, even if an error is detected, the system ECC driver 314 does not perform the error correction thereof. In parallel with the error check processing of the system ECC driver 314, the user data with the system ECCs is stored in the SRAM 318 (S15).

In parallel with the error check processing of the system ECC driver 314, the user data with the system ECCs is transmitted to the drive manager 315. In other words, the system ECC driver 314 executes the error check processing on the fly, and accordingly, the flow of the data transmission is not hindered. If an error is not detected by the system ECC driver 314 (NO in S14), the processing by the drive manager 315 is continued just as it is.

The drive manager 315 transmits the received data to the ECC correction processing part 316. The ECC correction processing part 316 generates a medium ECC from the data received from the drive manager 315. The medium ECC is a code for correcting an error during writing data to the magnetic disk 11.

The drive manager 315 acquires a medium ECC from the ECC correction processing part 316 to generate user data with a medium ECC and a system ECC (S16). Thus, the user data to which the system ECC and the medium ECC are added is transmitted as NRZ (Non-Return to Zero) data to the RW channel 21 through the data bus by the drive manager 315. If an error is not detected by the system ECC driver 314, the user data is transmitted to the magnetic disk 11 according to the above-described flow (S17).

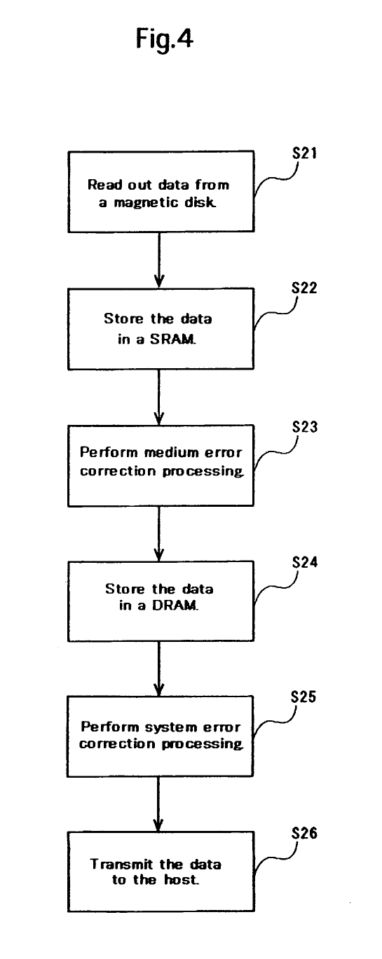

If an error is detected by the system ECC driver 314 (YES in S14), the MPU 232 which is an example of the error correction processing part executes the error correction processing by use of the SRAM 318. Before this point is described in detail, the flow of data transmission at the time of read processing will be described with reference to flowcharts shown in FIGS. 2 and 4. If a cache hit does not occur in response to a read command received from the host 51, required data is read out from the magnetic disk 11 (S21). During read operation of reading out data from the magnetic disk 11, the drive manager 315 receives, from the RW channel 21, user data to which a system ECC and a medium ECC are added, and then transmits the user data to the ECC correction processing part 316.

The ECC correction processing part 316, which is an example of the error correction processing part, corrects an error of data constituted of the user data and the system ECCs by use of the medium ECC if necessary. To be more specific, the ECC correction processing part 316 stores the data received from the drive manager 315 in the SRAM 318 that is an example of an error correction memory (S22). In addition, the ECC correction processing part 316 generates data used for error correction.

To be more specific, the ECC correction processing part 316 generates an ECC syndrome and a CRC syndrome on the basis of the data received from the drive manager 315. If the ECC and CRC syndromes are zero, this means that no error has occurred. Accordingly, data is transmitted without performing error correction. If the ECC and CRC syndromes are not zero, the ECC correction processing part 316 calculates, from the ECC syndrome, error data including an error position and an error pattern. Moreover, the ECC correction processing part 316 calculates the CRC syndrome on the basis of the result of calculating the error data, and then judges on the basis of the CRC syndrome whether or not all of the error data is correct. If it is judged that all of the error data is correct, the ECC correction processing part 316 corrects the data including the user data and the system ECCs according to the error data.

The ECC correction processing part 316 reads out from the SRAM 318 the user data with the system ECC data, which has been stored beforehand, and then performs correction processing by calculating exclusive OR between the error data and the data that has been read out (S23). The above-described processing is executed on the fly, and can be executed without interrupting data transmission. Because the on-the-fly processing is performed, the SRAM 318 has a plurality of pages of buffer. To be more specific, while data of the previous sector is stored in a certain page of the buffer to execute the error correction processing, data of the next sector is stored in the next page. This prevents the data transmission from being interrupted. The use of the SRAM 318 during the medium error correction will be described in detail later.

If the error data is not correct, the ECC correction processing part 316 performs error correction by erasure correction processing. The erasure is an error that can be corrected if an error pattern is known. Through the erasure correction processing, a position at which the possibility of error is high is estimated as an erasure position, and error data is then calculated on the basis of this erasure position. The erasure correction processing is generally executed offline, and data transmission is interrupted. Incidentally, the above error correction technique is a well-known technology, and therefore detailed description of the calculation method thereof will be omitted.

Data, which has been subjected to medium error correction by the ECC correction processing part 316, is transmitted to the memory manager 313. This transmission data includes the user data and the system ECCs. The memory manager 313 temporarily stores received data in the DRAM 24 (S24), and then reads out this data from the DRAM 24 to transmit the data to the system ECC host 312.

The system ECC host 312 executes error correction of the received data if necessary (S25). The method of the error correction is substantially similar to that of the error correction performed by the ECC correction processing part 316. To be more specific, the system ECC host 312 temporarily stores the received data in the SRAM 317, and then executes the error correction processing by use of the system ECCs. This processing is executed on the fly. Accordingly, while correcting the user data, it is possible to transmit the user data from the system ECC host 12 to the HIC 311. The HIC 311 transmits the user data to the host 51 (S26). Up to this point, the read processing ends.

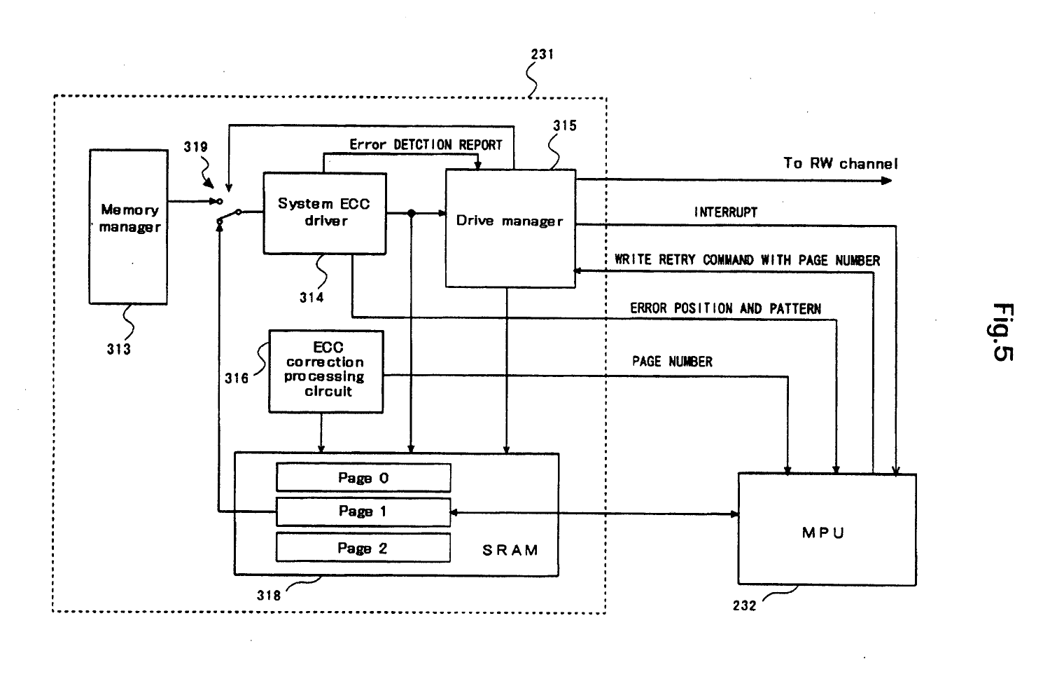

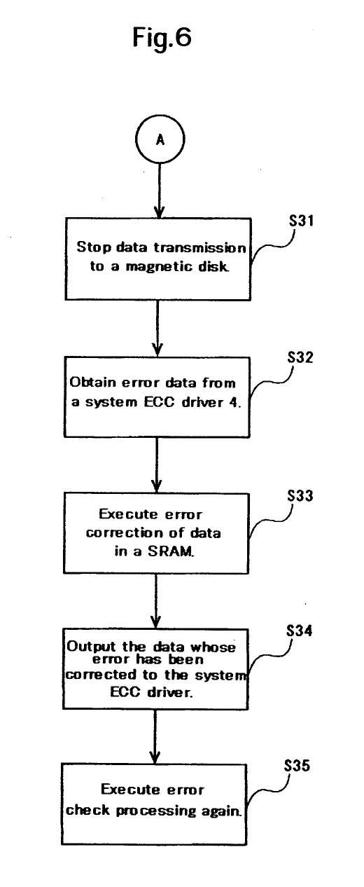

Processing in the case where the system ECC driver 314 detects an error in the above-described write processing will be described with reference to a block diagram in FIG. 5 and a flowchart in FIG. 6. As described above, the system ECC driver 314 executes the error check processing of data transmitted from the memory manager 313. Concurrently with the error check processing of user data, which is performed by the system ECC driver 314 by use of the system ECCs, the user data with the system ECCs is temporarily stored in the SRAM 318.

If the system ECC driver 314 detects an error of the user data, the system ECC driver 314 notifies the drive manager 315 that the error has been detected (ERROR DETECTION REPORT). In response to the notification of the error detection, the drive manager 315 stops the data transmission to the magnetic disk 11 (S31). Therefore, the following processing is executed off the fly. The drive manager 315 interrupts the MPU 232 (INTERRUPT). Incidentally, the drive manager 315 outputs a read control signal and a write control signal to the RW channel 21 to control data transmission between the magnetic disk 11 and the RW channel 21.

The interrupted MPU 232 refers to a status register of the drive manager 315. By checking data stored in the status register, the MPU 232 knows that the interruption is caused by the error detection by the system ECC driver 314. The MPU 232 performs the error correction of the user data with the system ECCs stored in the SRAM 318.

To be more specific, the MPU 23 obtains the error data from the system ECC driver 314 (S32), and thereby executes the error correction of the data in the SRAM (S33). The error data includes an error position (ERROR POSITION) and an error pattern (ERROR PATTERN). The system ECC driver 314 calculates this error data in the error check processing. To be more specific, the system ECC driver 314 generates an ECC syndrome and a CRC syndrome from the system ECCs and the user data so as to check whether or not an error has been detected. If it is judged that an error has been detected, the system ECC driver 314 calculates an error position and an error pattern by use of the ECC syndrome.

The system ECC driver 314 has a register. The system ECC driver 314 stores error data in the register. The interrupted MPU 232 accesses the register of the system ECC driver 314 to obtain the error data, and then uses the error data to correct the user data stored in the SRAM 318. Incidentally, the MPU 232 calculates a CRC syndrome by use of the data stored in the SRAM 318 and the error data. Then, on the basis of the CRC syndrome, the MPU 232 judges whether or not all of the error data is correct. If it is judged that all of the error data is correct, the ECC correction processing part 316 corrects the data including the user data and the system ECCs according to the error data. If the error cannot be corrected by the error data, processing corresponding to the error is executed. This processing will be omitted in this specification.

Upon the completion of the error correction by the MPU 232, the MPU 232 instructs the drive manager 315 to retry the write processing (WRITE ENTRY COMMAND WITH PAGE NUMBER). At this time, the MPU 232 also instructs the drive manager 315 to determine a page of the SRAM 318 from which data is to be read out. This point will be described later. The drive manager 315, which has been instructed by the MPU 232, sets a selector 319 for switching an input path leading to the system ECC driver 314.

The HDC 231 includes two input paths leading to the system ECC driver 314. One of the input paths is a path from the memory manager 313. This path is used to transmit, to the system ECC driver 314, user data with system ECCs read out from the DRAM 24. The other path is a path from the SRAM 318. This path is used to transmit, to the system ECC driver 314, the user data with the system ECCs whose error has been corrected in the SRAM 318.

The selector 319 selects one of the two paths. When the write processing is started, the selector 319 selects the path from the memory manager 313. Then, when the MPU 232 executes the error correction as a result of the detection of an error by the system ECC driver 314, the input into the system ECC driver 314 is switched to the path from SRAM 318 in response to an instruction from the drive manager 315.

In response to the instruction from the drive manager 315, the SRAM 318 outputs the data whose error has been corrected to the system ECC driver 314 (S34). The system ECC driver 314 executes again the error check processing of the user data with the system ECCs transmitted from the SRAM 318 (S35). If no error is detected, the drive manager 315 adds to the user data a medium ECC generated by the ECC correction circuit 316, and then transmits the user data to the RW channel 21.

After that, the drive manager 315 instructs the selector 319 to select the path from the memory manager 313. As a result, the data from the DRAM 24 is successively transmitted to the system ECC driver 314. Incidentally, if the system ECC driver 314 detects an error again, the above processing is repeated the specified number of times. Incidentally, if the error has not been corrected, other processing corresponding to the error is executed.

As described above, by adding ECCs to data before storing the data in the DRAM 24, and by performing error checking and error correction processing for the data to be transferred from the DRAM 24 to the magnetic disk 11, it is possible to cope with a data error without identifying an error case, for example, a defect of the data itself, a defect of the DRAM 24, or a defect existing in a path. In other words, although the system error processing according to this embodiment mainly targets an error in the DRAM 24, the system error processing can also cope with a system error in the HDC. In addition, by checking again an error of the data that has been corrected by the MPU 232, it is possible to cope with an error caused by a bug of microcodes and an error occurring in a transmission path.

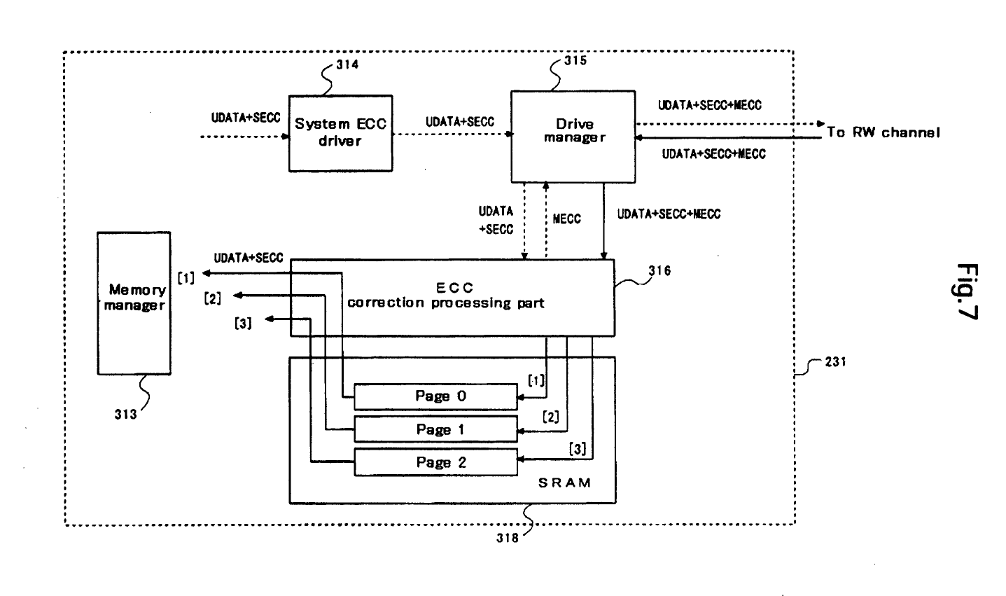

As shown in FIG. 5, the SRAM 318 has a plurality of pages of buffer. In this example, the SRAM 318 has three pages of buffer. Providing the SRAM 318 with a plurality of pages of buffer enables the ECC correction processing part 316 to perform the on-the-fly processing. The correction processing which is performed by the ECC correction processing part 316 using the SRAM 318 will be specifically described with reference to FIG. 7.

During read processing, the drive manager 315 obtains user data with a medium ECC and a system ECC from the magnetic disk 11. The data is transmitted on a data sector basis. The drive manager 315 transmits the data to the ECC correction processing part 316 on a data sector basis. The ECC correction processing part 316 performs calculation for error correction on a transmitted data sector basis. In parallel with the above calculation corresponding to one data sector, the ECC correction processing part 316 stores data of the data sector in a specific page of the SRAM 318.

The ECC correction processing part 316 successively stores data of each data sector in each of pages 0 through 2 of the buffer. To be more specific, at the time of read processing, the ECC correction processing part 316 stores data of a first data sector in the page 0 of the buffer, stores data of the next data sector in the page 1 of the buffer, and stores data of the next data sector in the page 2 of the buffer. After the data is stored in the page 2 of the buffer, the ECC correction processing part 316 stores data of the next data sector in the page 0 of the buffer again. Thus, the SRAM 318 successively stores inputted data of each data sector in each page.

When data of each data sector is read out from the SRAM 318, the data is successively read out from each page in like manner. If data is read out according to the order described in the above example, data of the data sector which is stored in the page 0 is first read out, and then data of the data sector stored in the page 1, that stored in the page 2, and that stored in the page 0 is read out in succession. The data which has been read out from each page is subjected to the error correction as a result of the calculation by use of an error pattern generated by the ECC correction processing part 316. The data whose error has been corrected is then transmitted to the memory manager 313.

The calculation for the error correction, which is performed by the ECC correction processing part 316, requires a length of time suitable for the calculation. Therefore, the data stored in the SRAM 318 is output after the completion of the calculation by the ECC correction processing part 316. During that time, data of the next data sector is transmitted from the magnetic disk 11. The SRAM 318 stores the data of the next data sector in a page that differs from the page in which data of the previous data sector is stored. Moreover, the ECC correction processing part 316 can complete the calculation corresponding to one data sector within a period of time during which data of two data sectors is transmitted.

For example, the calculation of the data stored in the page 0 can be completed before the data of the data sector is stored in the page 2. Accordingly, data of the next data sector can be stored in the page 0 without delay. As a result of the above-described buffer control, the ECC correction processing part 316 can execute the error correction processing on the fly without interrupting the data transmission from the magnetic disk 11.

Returning to FIG. 5, how to use the SRAM 318 in the system error correction processing will be described. As described above, in order to execute the medium error correction processing on the fly, data is successively stored in each of the plurality of pages of the SRAM 318. Moreover, the data is successively output from each of the pages in the order in which the data has been stored. However, because the system error correction processing corrects data of one data sector, only one page among the plurality of pages is used.

When the MPU 232 performs error correction, the MPU 232 is required to know a page in which data is stored. In this embodiment, the ECC correction circuit 316 controls storing of data in the SRAM 318. Therefore, the ECC correction processing part 316 notifies the MPU 232 of a page in which data to be subjected to the error correction is stored.

As is the case with the read processing, the user data with the system ECCs received from the system ECC driver 314 is successively stored in each page from the page 0. To be more specific, when the transmission of write data is started, data of the first data sector is stored in the page 0, and then data of the subsequent data sectors is stored in the order of the pages 1, 2. After that, data is stored again in the order of the pages 0, 1, 2 in like manner. If an error is not detected by the system ECC driver 314, data to be transmitted to the magnetic disk 11 is successively stored in each page. The ECC correction processing part 316 includes a register that stores data used to identify a page in which the next data should be stored.

If an error is detected in any data sector by the system ECC driver 314, the HDC 231 stops the processing as described above, and interrupts the MPU 232. The MPU 232 refers to the register of the ECC correction processing circuit 316, and thereby identifies a page in which data including the detected error is stored. By use of the error data obtained from the system ECC driver, the MPU 232 corrects the error of the data that is stored in the identified page.

Upon the completion of the error correction, the MPU 232 instructs the drive manager 315 to make a write retry. At this time, the MPU 232 specifies a page of the SRAM 318 from which writing of the data should be started. According to the instruction by the MPU 232, the drive manager 315 instructs the SRAM 318 to output data starting from the specified page. As a result, the system error is corrected.

Up to this point, the present invention has been described on the basis of the desirable modes. However, the present invention is not limited to the embodiments described above. As a matter of course, the present invention may be modified in various ways without departing from the scope of the present invention. For example, although the HDD was taken as an example in the above-described embodiments, the present invention may also be applied to a data storage device that uses another medium such as an optical disc and a magnetic optical disc, or a data storage device that is capable of using the medium as a removable medium.

It is desirable that a DRAM be used as a buffer memory, whereas a SRAM be used as a memory in the HDC. However, the types of memories are not limited to those described above, and other types of memories may also be used. The number of pages of the SRAM is not limited to three. Preferably, the optimal number of pages is selected according to the design. In addition, although it is desirable that one page have the capacity of one data unit or more, the present invention is not limited to this. The above-described ECC correction processing part generates ECCs from data obtained from the drive manager. However, the ECC correction processing part may also be configured to obtain data from the system ECC driver, and then to transmit the data with the ECCs to the drive manager.

What is claimed is:

1. A data storage device comprising:
a buffer memory for storing write data received from the outside;
a first error correction part for executing error correction processing of the write data that is transmitted from the buffer memory to a medium;
a second error correction part for executing error correction processing of read data read out from the medium; and
an error correction memory for temporarily storing the write data from the buffer memory, and for temporarily storing the read data read out from the medium, the write data being subjected to the error correction processing of the first error correction part, the read data being subjected to the error correction processing of the second error correction part.

2. The data storage device according to claim 1, wherein
the first error correction part is a processor that operates according to codes, and the second error correction part is a hardware circuit for executing the error correction processing on the fly.

3. The data storage device according to claim 1, further comprising an error check circuit for checking an error of the write data that is transmitted from the buffer memory to the medium,
wherein:
in parallel with the processing of the error check circuit, the write data from the buffer memory is stored in the error correction memory, and is also transmitted to the medium; and
if the error check circuit detects an error, the first error correction part executes the error correction processing of the write data whose error has been detected.

4. The data storage device according to claim 1, further comprising:
a path through which data from the buffer memory is transmitted to the error check circuit; and
a path through which data is transmitted from the error correction memory to the error check circuit,
wherein:
if the first error correction part executes the error correction, the path through which data is transmitted from the error correction memory to the error check circuit is selected.

5. The data storage device according to claim 1, wherein:
the error correction memory comprises a plurality of pages of buffer;
the read data from the medium is successively inputted into each of the plurality of pages, and is output from the error correction memory in the order of the input;
the write data from the buffer memory is stored in part of the plurality of pages;
the first error correction part obtains data for identifying a page in which the write data is stored, and then executes the error correction processing of the stored write data; and
the error correction memory selects the page in which the write data whose error has been corrected is stored, and then outputs the data from the page.

6. The data storage device according to claim 3, further comprising an ECC addition circuit for adding an ECC to the write data received from the outside,
wherein:
the buffer memory temporarily stores the write data to which the ECC is added; and
the error check circuit uses the ECC to execute error detection processing of the write data transmitted from the buffer memory.

7. The data storage device according to claim 3, wherein
the first error correction part obtains an error position and an error pattern from the error check circuit to execute the error correction of the write data.

8. A method for performing error correction of data in a data storage device, the method comprising the steps of:
storing, in a memory, write data that is transmitted from a buffer memory to a medium;
executing error correction processing of the write data stored in the memory;
transmitting, to the medium, the write data whose error has been corrected;
storing, in the memory, read data read out from the medium; and
executing error correction processing of the read data stored in the memory.

9. The method according to claim 8, wherein:
the write data to which an ECC is added is stored in the buffer memory;
the write data having the ECC, which is transmitted from the buffer memory to the medium, is stored in the memory; and
if an error is detected in the write data transmitted from the buffer memory, error correction processing of the write data stored in the memory is executed by use of the ECC.

10. The method according to claim 8, wherein:
the error check processing of the write data to be transmitted to the medium is executed;
in parallel with the error check processing, the write data to be transmitted to the medium is stored in the memory; and
if an error is detected in the write data during the error check processing, error correction processing of the write data stored in the memory is executed.

11. The method according to claim 8, wherein:
the read data from the medium is successively inputted into each of a plurality of pages of the memory and output from the memory in the order of the input;
the write data from the buffer memory is stored in one of the plurality of pages;
error correction processing of the stored write data is executed; and
after selecting the page in which the write data whose error has been corrected is stored, the data is output from the page.
